(19) United States
(12) Patent Application Publication
(10) Pub. No.: US 2026/0334290 A1
(43) Pub. Date: Oct. 22, 2026

(54) POWER SEMICONDUCTOR DEVICE PACKAGE WITH BUFFER MATERIAL

(71) Applicant: Microchip Technology Incorporated, Chandler, AZ (US)

(72) Inventors: Fernando Estrada, Mesa, AZ (US); Shesh Pandey, Gilbert, AZ (US)

(73) Assignee: Microchip Technology Incorporated, Chandler, AZ (US)

(21) Appl. No.: 19/247,617

(22) Filed: Jun. 24, 2025

Related U.S. Application Data
(60) Provisional application No. 63/792,104, filed on Apr. 21, 2025.

(51) Int. Cl. H10W 74/10; H10W 70/40; H10W 74/01; H10W 74/47; H10W 90/00

(52) U.S. Cl. CPC H10W 74/121; H10W 70/481; H10W 74/01; H10W 74/47; H10W 90/755

(57) ABSTRACT

A semiconductor device package comprising a frame comprising a conductive material, the frame comprising a plurality of connectors; a die attached to the frame, the die comprising a semiconductor device; a first dielectric material in contact with at least a portion of a top surface of the die and a portion of the frame; and a second dielectric material encapsulating the first dielectric material.

### CROSS-REFERENCE TO RELATED APPLICATION

The present application claims priority to U.S. Provisional Patent Application No. 63/792,104, filed on Apr. 21, 2025, the contents of which are hereby incorporated by reference in their entirety.

### TECHNICAL FIELD

The present disclosure relates generally to semiconductor device packaging, and more specifically to a power semiconductor device package with buffer material.

### BACKGROUND

A power semiconductor device package is a physical enclosure for protecting a power semiconductor device (such as a transistor, diode, or thyristor) designed to handle high voltages and currents. Power semiconductor device packages and their underlying devices may be used in a wide variety of applications, including, e.g., power supplies, motor drives, solar inverters, and electric vehicles.

### SUMMARY OF THE INVENTION

Aspects provide a power semiconductor device package with buffer material.

In one aspect, a semiconductor device package comprises a frame comprising a base portion and a plurality of connectors extending outwardly from the base portion; a die attached to the base portion of the frame, the die comprising a semiconductor device comprising at least one terminal coupled to at least one of the plurality of connectors of the frame; a first dielectric material in contact with at least a portion of a top surface of the die and a portion of the base portion of the frame; and a second dielectric material encapsulating the first dielectric material.

In another aspect, a method for forming a semiconductor device package comprises attaching a die comprising a semiconductor device to a base portion of a frame, the frame comprising the base portion and a plurality of connectors extending outwardly from the base portion; forming a first dielectric material on the die and on a portion of the frame; and encapsulating the first dielectric material with a second dielectric material.

In yet another aspect, an apparatus comprises a semiconductor device package comprising a frame comprising a surface and a plurality of connectors; a die attached to the surface, the die comprising a semiconductor device comprising at least one terminal coupled to at least one of the plurality of connectors of the frame; a first dielectric material in contact with at least a portion of a top surface of the die; and a second dielectric material on the first dielectric material.

### BRIEF DESCRIPTION OF THE DRAWINGS

FIG. 1 illustrates a lead frame of a plug-in semiconductor device package comprising a through-hole, in accordance with any of the examples disclosed herein.

FIG. 2 illustrates the lead frame with a die comprising a semiconductor device attached thereto, in accordance with any of the examples disclosed herein.

FIG. 3 illustrates wires connecting the die to connectors of the lead frame, in accordance with any of the examples disclosed herein.

FIG. 4 illustrates a buffer material applied on the die that is attached to the lead frame, in accordance with any of the examples disclosed herein.

FIG. 5 illustrates a top view of a plug-in semiconductor device package after application of an encapsulating material, in accordance with any of the examples disclosed herein.

FIG. 6 illustrates a bottom view of the plug-in semiconductor device package, in accordance with any of the examples disclosed herein.

FIG. 7 illustrates a lead frame of a surface mount semiconductor device package, in accordance with any of the examples disclosed herein.

FIG. 8 illustrates the lead frame of the surface mount semiconductor device package and a die comprising at least one semiconductor device attached to the lead frame, in accordance with any of the examples disclosed herein.

FIG. 9 illustrates wires connecting the die to connectors of the lead frame, in accordance with any of the examples disclosed herein.

FIG. 10 illustrates a buffer material applied around the die attached to the surface mount semiconductor device package, in accordance with any of the examples disclosed herein.

FIGS. 11-12 illustrate top and bottom views of the surface mount semiconductor device package after application of an encapsulating material, in accordance with any of the examples disclosed herein.

FIG. 13 illustrates a system comprising a semiconductor device package comprising a buffer material, in accordance with any of the examples disclosed herein.

FIG. 14 illustrates a flow for forming a semiconductor device package comprising a buffer material, in accordance with any of the examples disclosed herein.

### DETAILED DESCRIPTION

Standard discrete semiconductor device packages may present one or more high stress interfaces between the die comprising one or more semiconductor devices and the material that encapsulates the die. Such stress may result, at least in part, from the interface between the dissimilar materials of the encapsulating material and the die. For example, the dissimilar materials may have different coefficients of thermal expansion, glass transition temperatures, or other properties that make the interface susceptible to mechanical damage and impaired electrical performance characteristics as a result of temperature cycling. Such stress may be especially prominent at the corners and on the top of the die. Package designs with low thickness further complicate the ability to reduce the stress on the die.

Various examples of the present disclosure provide a power semiconductor device package with a buffer material in between the die and the encapsulating material. In some examples, a die comprising the semiconductor device is attached to a surface of a frame and the buffer material is formed over the die. In some examples, the buffer material comprises an underfill material. An encapsulating material is then placed over the buffer material. In various examples, the buffer material prevents the encapsulating material from contacting the die, thus providing thorough stress protection to the die by relieving or mitigating stress between the encapsulating material and the die. Various examples may provide one or more technical advantages, such as improved package robustness, configurability, lifetime reliability, thermal performance, or electrical management.

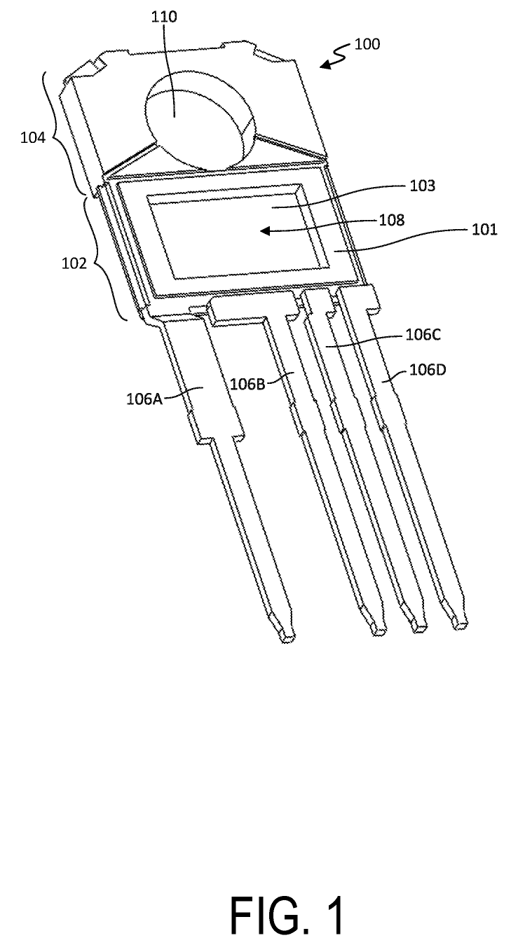

FIG. 1 illustrates a lead frame 100 of a plug-in semiconductor device package comprising a through-hole 110, in accordance with any of the examples disclosed herein. The lead frame 100 includes a base portion 102 (e.g., a die attach paddle), a through-hole block 104, and connectors 106A-D (e.g., lead posts or pins). In various examples, the base portion 102, through-hole block 104, and connector 106A are electrically conductively coupled together. For example, these components of the lead frame 100 may be one continuous piece of a conductive material, such as a metal (e.g., copper) or metal alloy.

The base portion 102 is the portion of the lead frame 100 that is to interface with the die that comprises at least one semiconductor device (e.g., power semiconductor device). In various examples, the base portion may have at least one substantially flat surface that is to be attached to the die. In the example depicted, the base portion 102 includes a cavity 108 on its top side. In this example, at least a portion of the die is to be placed within the cavity. In an example, the surface 103 of the base portion 102 at the bottom of the cavity 108 may be substantially flat. In some instances, the surface 101 or surface 103 of the base portion 102 may include features (such as dimples or micro-grooves) that facilitate adhesion of dielectric material to the base portion 102. The cavity may have any suitable depth within the base portion 102. In various examples, the cavity has a depth that is greater in magnitude than the height (e.g., thickness) of the die to be placed therein, such that the buffer material may be placed in the cavity and over the attached die without spilling over the edges of the cavity. As just one example, when the overall height (e.g., thickness) of the base portion 102 is about 2 mm, the depth of the cavity may be about 1 mm.

The base portion 102 includes an additional surface 101 that forms a perimeter around the portion that is recessed within the cavity 108. In this example, the surface 101 is substantially flat.

The through-hole block 104 includes a through-hole 110 that passes completely through the through-hole block 104. When the through-hole semiconductor device package is attached to a printed circuit board or other system component, a fastening means (e.g., a screw) may be placed through the through-hole block 104 to fasten the semiconductor device package to the circuit board.

The lead frame 100 illustrates a frame for a plug-in type package. A plug-in type package may include connectors designed to be inserted into holes in a printed circuit board and soldered to the printed circuit board. Other plug-in type packages in accordance with any of the examples herein may omit the through-hole block 104 and the through-hole 110 (potentially achieving a more compact design).

In the example depicted, the lead frame 100 includes four connectors 106 (e.g., lead posts, pins) that extend outwardly from the base portion 102. In other examples, a semiconductor device package may include any suitable number of connectors (e.g., two connectors, three connectors, or more than four connectors). The lead frame 100 depicted may represent a lead frame 100 for a package that includes a die comprising a power MOSFET. In this example, once assembly of the package is complete, the connector 106A may be electrically conductively coupled to a drain terminal, connector 106B may be electrically conductively coupled to a source terminal, connector 106C may be electrically conductively coupled to a different portion of the source terminal, and connector 106D may be electrically conductively coupled to a gate terminal of the power MOSFET. In this example, the connectors 106A-D may each be electrically isolated from each other (at least before the die is connected). For example, the connector 106A may be connected directly to the base portion 102, while connectors 106B-D may be connected to the base portion 102 through respective portions comprising a dielectric material to electrically isolate the connectors 106B-D from the base portion 102. In some examples, connectors 106B-D may be electrically isolated from the rest of the lead frame 100 and may ultimately be connected to the die via respective wires.

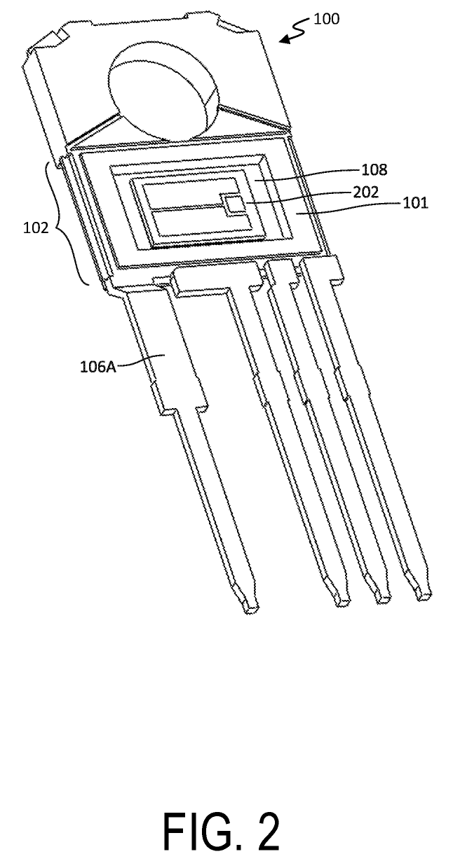

FIG. 2 illustrates the lead frame 100 with a die 202 comprising a semiconductor device attached thereto, in accordance with any of the examples disclosed herein. In this FIG., die 202 comprising the semiconductor device is placed within the cavity 108 and attached to the base portion 102 of the lead frame 100. In this example, the bottom side of the die 202 may be attached to the top surface of the base portion 102 within the cavity 108. Continuing with the example in which the die 202 comprises a power MOSFET, the bottom side of the die may include conductive material comprising the contact for the drain terminal of the MOSFET, which is thus electrically conductively coupled to the connector 106A through the base portion 102. The die 202 may be attached to the base portion 102 in any suitable manner, such as through a conductive die attach material such as solder (e.g., lead solder wire or solder paste) or conductive epoxy. In some instances the die attach material may be applied after the lead frame 100 is heated, e.g., via a dispense process or solder wire process. After the die is placed on the base portion 102, a reflow process may set the die attach material.

In various examples, the height (e.g., thickness) of the die 202 may be smaller than the depth of the cavity, such that when attached to the base portion 102, the top surface of the die 202 is lower than the top surface 101 of the base portion 102. This may simplify application of the buffer material, as the buffer material move (e.g., from the top of the die 202) into portions of the cavity 108 that are not occupied by the die. In other examples, the thickness of the die 202 may be equal to or greater than (e.g., slightly greater than) the depth of the cavity (e.g., if the buffer material may be applied with relative precision such that it does not significantly overflow and cause complications with subsequent processing operations).

The die 202 may include one or more semiconductor devices (such as a power semiconductor device) formed in a substrate (e.g., comprising silicon, silicon carbide, gallium nitride, or the like). A power semiconductor device may include any suitable semiconductor device that can accommodate high voltage (e.g., between 10V-8000V, but not limited thereto) applied to one or more terminals or high current (e.g., between 5A-1000A, but not limited thereto) flowing through one or more terminals. As examples, a power semiconductor device may comprise a metal-oxide-semiconductor field-effect transistor (MOSFET), a junction field-effect transistor (JFET), an insulated gate bipolar transistor (IGBT), a bipolar junction transistor (BJT), a thyristor, a diode, or the like. In some examples, the die 202 includes a single discrete semiconductor power device. In other examples, the die 202 includes a plurality of semiconductor power devices (e.g., a pair of power semiconductors, such as a field-effect transistor (FET) coupled to a diode).

In some examples, the die 202 may include one or more dielectric layers formed over at least a portion (e.g. a majority) of the surface area of the top of the die. For example, a dielectric layer may comprise an oxide, a nitride, or polyimide. In some examples, the top layer of the die comprises a polyimide layer. In various examples, the top surface of the die may include one or more other layers, and any of these layers may contact the buffer material once the buffer material is applied. For example, the top surface of the die may include a passivation layer (comprising, e.g., silicon nitride, silicon dioxide, or other dielectric material). As another example, the top surface of the die may include the top layer of metal of one or more conductive contacts (e.g., bond pads) comprising, e.g., aluminum, gold, or silver. The conductive contacts may be connected to terminals of the one or more semiconductor devices of the die 202. In one example, a layer comprising polyimide may cover the top surface of the die except the areas of the top surface in which the conductive contacts are exposed.

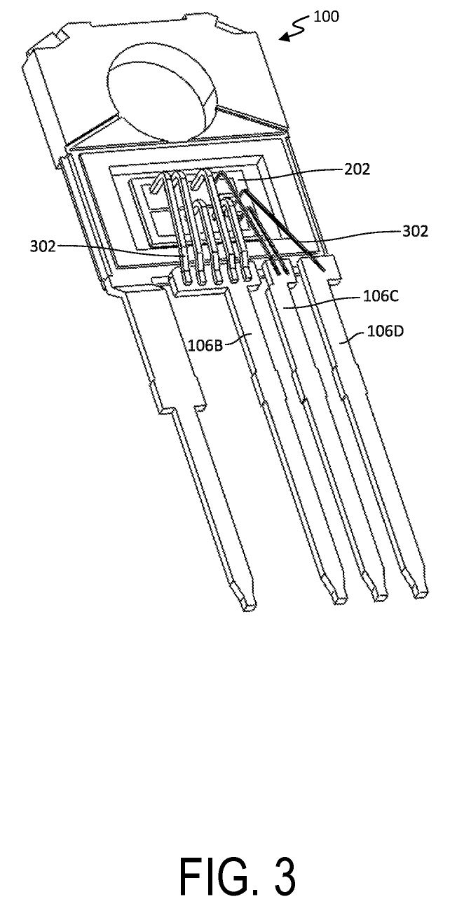

FIG. 3 illustrates wires 302 connecting the die 202 to connectors 106 of the lead frame 100, in accordance with any of the examples disclosed herein. After the die 202 is attached to the lead frame 100, wires are formed (using any suitable wire bonding techniques) from conductive contacts (e.g., bond pads) of the die 202 to respective connectors 106 of the lead frame 100. In the example depicted, five wires 302 are connected to connector 106B, two wires 302 are connected to connector 106C, and one wire is connected to connector 106D. The wires may include a conductive material, such as copper, aluminum, or gold. Continuing the example above in which the die 202 includes a power MOSFET, the five wires 302 may connect the conductive contacts for the source terminal of the power MOSFET to the connector 106B, the two wires may connect other portions of the conductive contacts for the source terminal of the power MOSFET to the connector 106C (which may be referred to as the source sense pin), and one wire may connect the conductive contact for the gate terminal of the power MOSFET to the connector 106D.

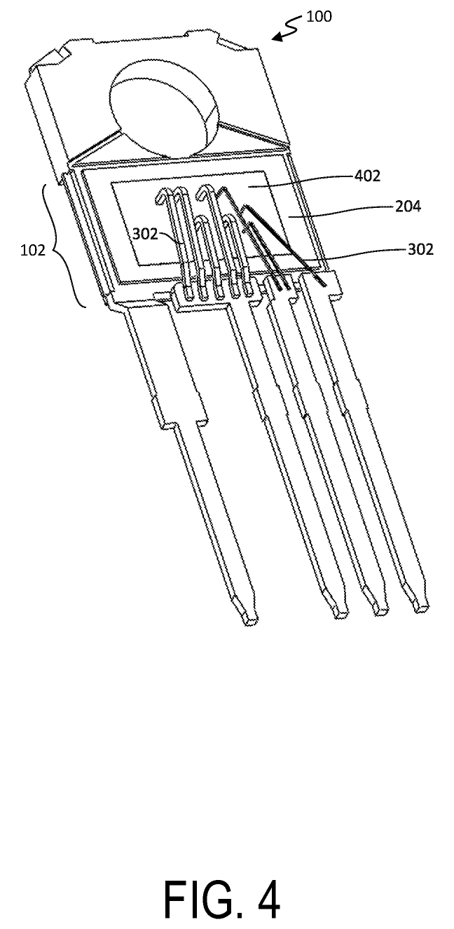

FIG. 4 illustrates a buffer material 402 applied on the die 202 that is attached to the lead frame 100, in accordance with any of the examples disclosed herein. After the die 202 is attached to the lead frame 100 and the wires 302 are formed, buffer material 402 is placed on and around the die 202. For example, the buffer material 402 may be on at least a portion of the top surface of the die 202 or at least a portion of the side surfaces of the die 202. The buffer material 402 may also be placed on the lead frame 100 (e.g., on at least a portion of one or more surfaces of the base portion 102). In the example depicted, the portion of the cavity 108 that is not occupied by the die 202 is completely filled with the buffer material 402. In other examples, the portion of the cavity that is not occupied by the die 202 may be partially filled with the buffer material 402. In the example depicted, the top surface of the applied buffer material 402 may be at substantially the same level as the top surface 101 of the base portion 102 that forms the perimeter of the cavity 108. In other examples, the top surface of the applied buffer material 402 may be above or below the top surface 101 (or above in some spots, at the same level in some spots, or below in some spots). In some instances, the buffer material 402 may spill over (e.g., slightly over) the edge of the cavity 108 and onto at least a portion of the top surface 101.

In various examples, the buffer material 402 may cover the entire top surface of the die 202 (e.g., other than the portions occupied by wires 302 extending upwards from the top surface of the die) and the sides of the die 202 (while the bottom surface of the die 202 is attached to the lead frame 100). In some examples, the buffer material 402 may cover a majority (e.g., a substantial majority) of the top surface of the die 202 or the sides of the die 202. In various examples, the buffer material 402 may also cover a portion of the wires (e.g., proximate the portions of the wires 302 that connect to the die 202). For example, the buffer material 402 may encapsulate an outer perimeter of the portions of any number of the wires 302.

Buffer material 402 may comprise a dielectric material (e.g., for high voltage insulation) that is suitable to absorb stress from an encapsulating material to protect the die 202. In some examples, the buffer material 402 has good thermal conductivity (e.g., greater than 10 watts per meter-kelvin (W/m·K)) to provide beneficial heat spreading capabilities. In other examples, the buffer material has a thermal conductivity that is greater than 1 W/m·K. In various examples, the buffer material may have a coefficient of thermal expansion (CTE) value that is similar to a CTE value of the encapsulating material (e.g., within 10%). In various examples, the buffer material may have a dielectric constant that is similar to (e.g., within 10% of) a dielectric constant of the encapsulating material.

In some examples, the buffer material 402 comprises an underfill material that comprises epoxy or silicone (e.g., an epoxy-based underfill or a silicone-based underfill). For example, the buffer material 402 may comprise a thermosetting resin, such as an epoxy resin. In some instances, the buffer material 402 may include fillers, such as silica, alumina, boron nitride, or other suitable fillers.

The buffer material 402 may be applied to the lead frame 100 in any suitable manner. In various examples, the buffer material 402 may be in a liquid form that is dispensed onto the lead frame 100 and die 202 and then cured to solidify the buffer material 402. Alternatively, the buffer material 402 may be injected onto the lead frame 100 and die 202.

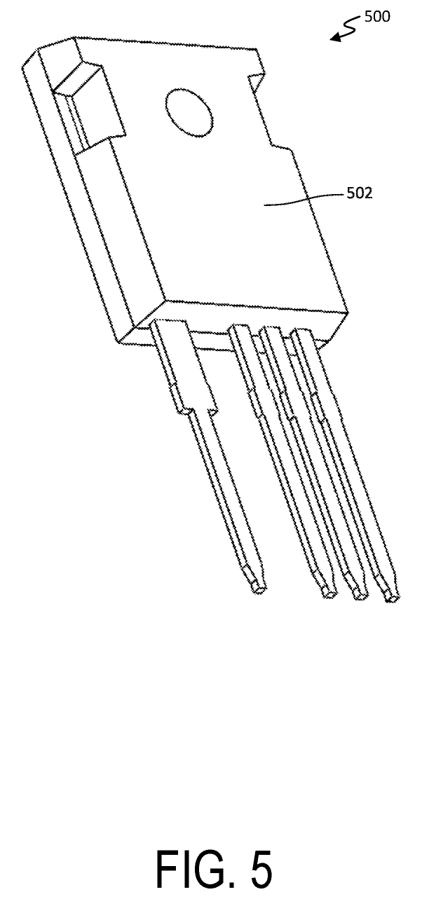

FIG. 5 illustrates a top view of a plug-in semiconductor device package 500 comprising lead frame 100 and base portion 102 after application of encapsulating material 502, in accordance with any of the examples disclosed herein. The encapsulating material 502 may electrically isolate the semiconductor device(s) of die 202 from the outside environment and protect the device. The encapsulating material 502 is applied around (and in contact with) the lead frame 100, buffer material 402, wires 302, or portions of the connectors 106.

The encapsulating material 502 may contact the buffer material 402 and the wires 302. For example, the encapsulating material 502 may fully encapsulate the buffer material 402 and the wires 302 and protect them from the outside environment. In this example, the encapsulating material 502 is not in contact with the die 202, but rather the buffer material 402 is between the die 202 and the encapsulating material 502, thus providing various advantages as described above.

The encapsulating material 502 may comprise a dielectric material. For example, the 502 may comprise an epoxy molding compound (e.g., a thermosetting resin, possibly comprising a filler such as silica, alumina, or aluminum nitride). Other examples of materials that may be used as an encapsulating material 502 include polyimide, silicone dielectrics, ceramic insulators, glass dielectrics, or organic materials. In various instances, the encapsulating material 502 may have a relatively high dielectric constant to prevent against breakdown between the top and bottom of the semiconductor device.

In some instances, the encapsulating material 502 may have a lower thermal conductivity than the buffer material 402. As an example, the thermal conductivity of the encapsulating material 502 may be about 1 W/m·K or lower. In various examples, when the buffer material 402 has a higher thermal conductivity than the encapsulating material 502, heat distribution is improved resulting in better electrical performance, reliability, or endurance of the die 202. In other examples, the encapsulating material 502 has a substantially similar or higher thermal conductivity relative to the buffer material 402.

In the example depicted, at least a portion of the through-hole 110 is maintained after formation of the encapsulating material 502. The encapsulating material 502 may encapsulate at least a portion of the base portion 102 (e.g. portion of the base portion could be exposed for thermal mitigation purposes).

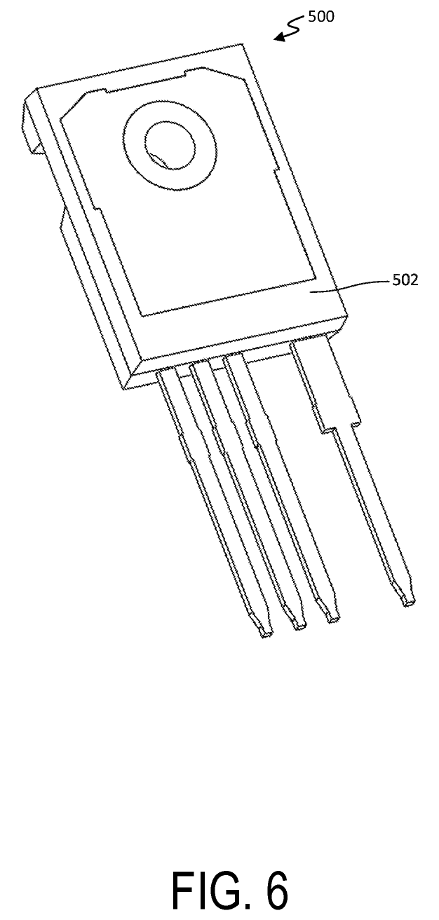

FIG. 6 illustrates a bottom view of the plug-in semiconductor device package 500, in accordance with any of the examples disclosed herein.

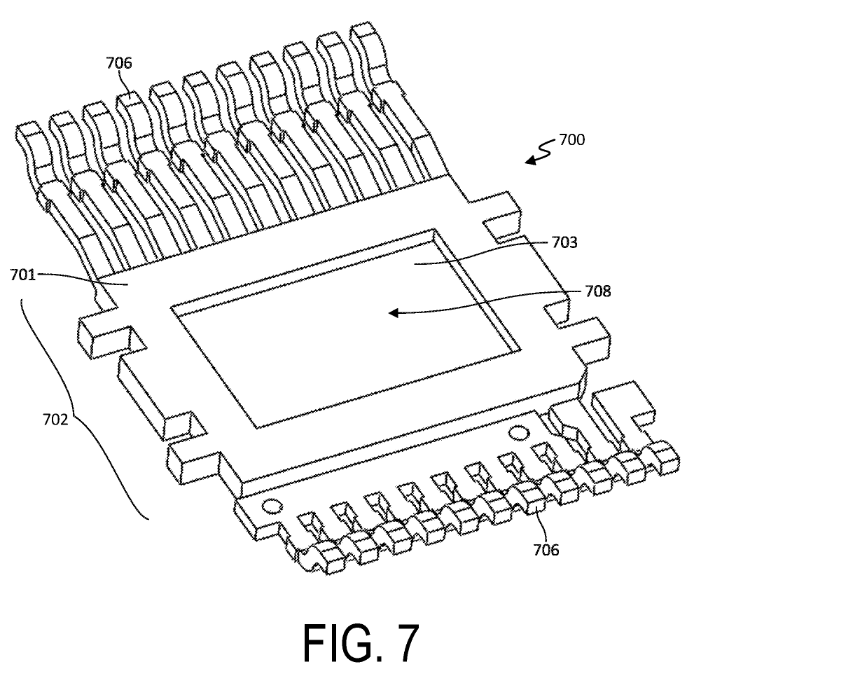

The concepts discussed above with respect to a plug-in semiconductor device package may be applied to any suitable semiconductor device package (e.g., plug-in semiconductor device packages without through-holes, other plug-in semiconductor device packages with through-holes, surface mount semiconductor device packages, or other suitable types of semiconductor device packages). FIGS. 7-12 illustrate an example of such concepts applied with respect to a surface mount semiconductor device package. Components of FIGS. 7-12 may have any suitable features of similar components of FIGS. 1-6.

FIG. 7 illustrates a lead frame 700 of a surface mount semiconductor device package, in accordance with any of the examples disclosed herein. The lead frame 700 includes a base portion 702 (which in some instances may be a die attach paddle). In this example, a cavity 708 is formed in the base portion 702. Thus, the base portion 702 includes a first surface 701 forming a perimeter around the cavity and a second surface 703 at the edge of the cavity. In this example, the first surface 701 and second surface 703 are both substantially flat.

The lead frame 700 also includes a plurality of connectors 706 (also commonly referred to as lead posts or pins) that extend outwardly from the base portion 702. The connectors may be arranged into two sets of connectors on opposite sides of the lead frame 700, with one set extending outwardly from the base portion 702 in a first lateral direction and the other set extending outwardly from an opposite side of the base portion 702 in a second lateral direction opposite to the first lateral direction. The connectors may include curvature, such that they also extend in a vertical direction from the base portion 702. In some examples, one or more of the connectors may be electrically conductively coupled to the base portion 702 while the other connectors are electrically isolated from the base portion 702.

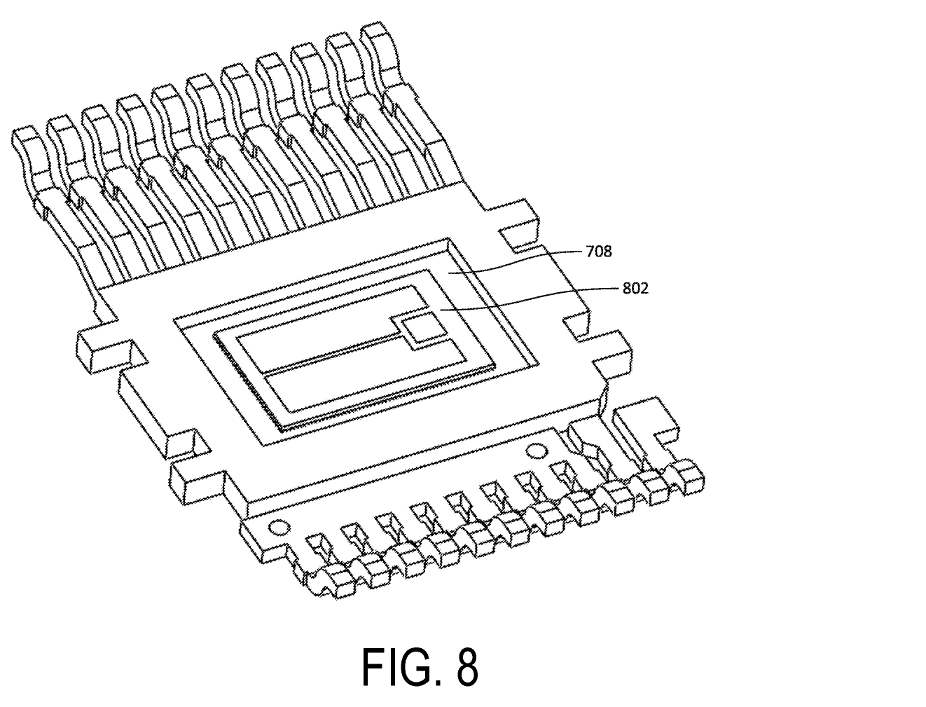

FIG. 8 illustrates the lead frame 700 of the surface mount semiconductor device package and a die 802 comprising at least one semiconductor device attached to the lead frame 700, in accordance with any of the examples disclosed herein. As depicted, the die 802 is placed within the cavity 708 and a bottom surface of the die 802 is attached to the surface 703. In various examples, the height (e.g., thickness) of the die 802 may be smaller than, equal to, or greater than the depth of the cavity 708. Die 802 may have any suitable characteristics of die 202.

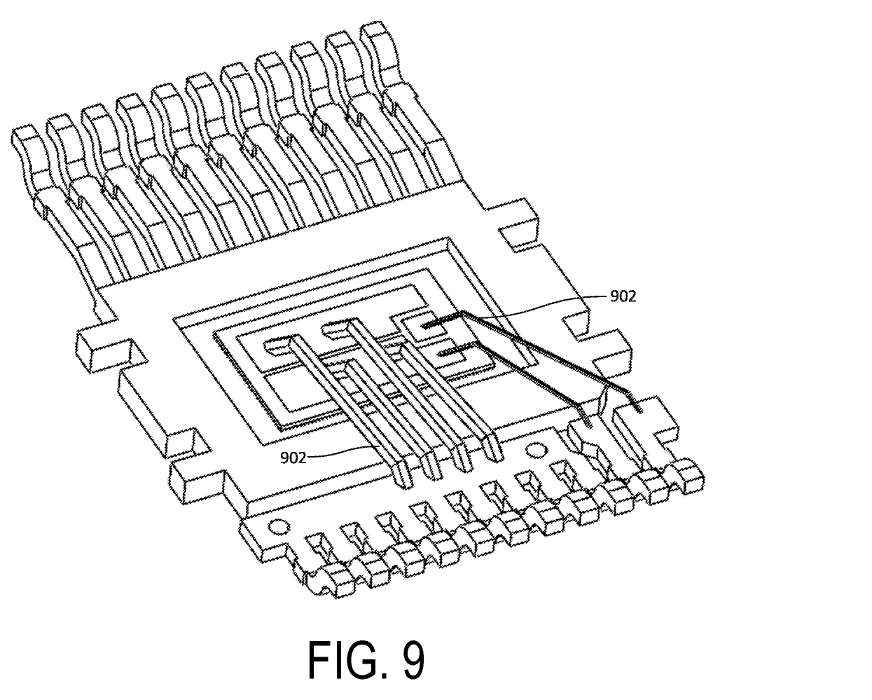

FIG. 9 illustrates wires 902 connecting the die 802 to connectors 706 of the lead frame 700, in accordance with any of the examples disclosed herein. In the example depicted, some of the connectors (e.g., a first set of connectors on one side of the lead frame 700) are not electrically connected to any of the wires, but rather to the base portion 702 (and thus to the bottom surface of the die 802, which may comprise, e.g., a drain contact of a power MOSFET or other suitable contact). Other connectors 706 are connected to one or more respective wires 902 which are also connected to various contacts of the die 802. In the example depicted, four wires (e.g., that are connected to two source pads of a power MOSFET of the die 802) connect to a set of nine adjacent connectors 706, another wire (e.g., that is connected to a gate pad of the power MOSFET) connects to one connector 706, and another wire (e.g., that is connected to a different location on the source pad) connects to the last connector.

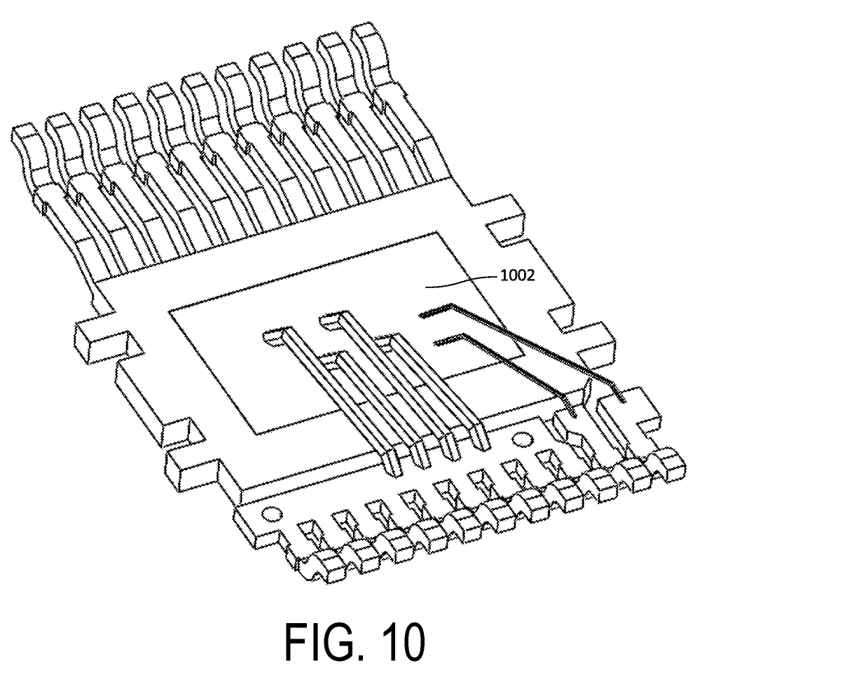

FIG. 10 illustrates a buffer material 1002 applied around the die attached to the surface mount semiconductor device package, in accordance with any of the examples disclosed herein. The buffer material 1002 may have any suitable characteristics of the buffer material 402. In the example depicted, the buffer material 1002 is substantially co-planar with the surface 701, but in other examples the buffer material 1002 may include one or more portions that are not co-planar with the surface 701 (or could even have portions that are disposed on a portion of the surface 701).

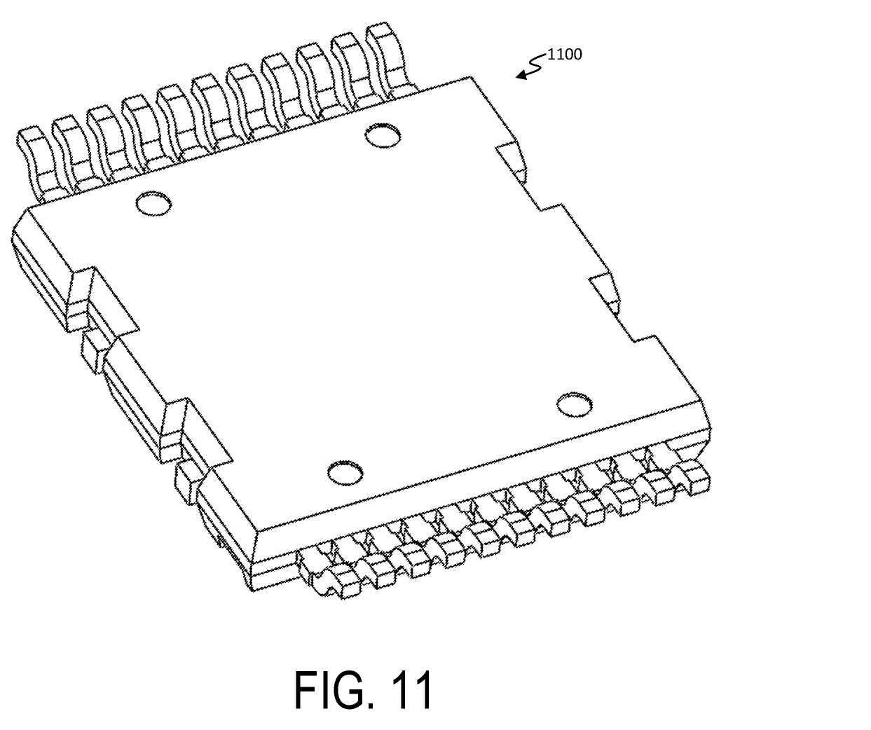

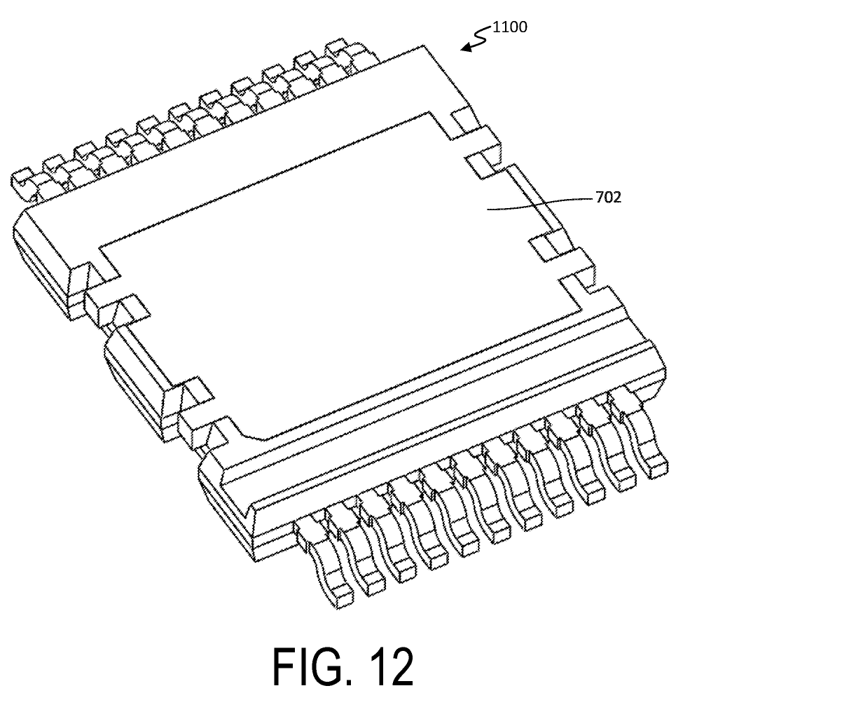

FIG. 11 illustrates a bottom view and FIG. 12 illustrates a top view of a surface mount semiconductor device package 1100 after application of the encapsulating material 1102, in accordance with any of the examples disclosed herein. The encapsulating material 1102 may have any suitable characteristics of the encapsulating material 502 (e.g., the encapsulating material 1102 may fully encapsulate the buffer material 1002 and the wires 902). The encapsulating material 1102 may contact the buffer material 1002 and the wires 902. For example, the encapsulating material 1102 may fully encapsulate the buffer material 1002 and the wires 902 and protect them from the outside environment. In this example, the encapsulating material 1102 is not in contact with the die 802, but rather the buffer material 1002 is between the die 802 and the encapsulating material 1102, thus providing various advantages as described above.

In the example depicted in FIG. 12, the conductive material of the base portion 702 is exposed at the top (e.g., so that a heatsink may be connected to the package 1100). Thus, in some examples, the 1102 does not encapsulate the entire base portion 702, but just a portion thereof.

While the examples above illustrate dies and buffer materials placed within cavities of lead frames, the concepts described herein may be applied to other suitable package architectures. For example, instead of forming the buffer material at least partially within a cavity, a ridge (e.g., with a square, rectangular, or other closed shape) may be formed on a top surface of a body portion (e.g., die attach paddle) of a lead frame and the die and buffer material may be placed on the inside of the ridge, with the ridge containing the buffer material to the area within the ridge. As another example, the body portion (e.g., die attach paddle) may have a substantially flat surface and the die may be attached to the surface (e.g., at or near the center of the surface) and the buffer material may be formed on the die and on a portion of the surface, so as to surround the die. Such an example may be feasible if the placement of the buffer material may be tightly controlled so as not to result in the buffer material entering unwanted areas and affecting subsequent processing operations.

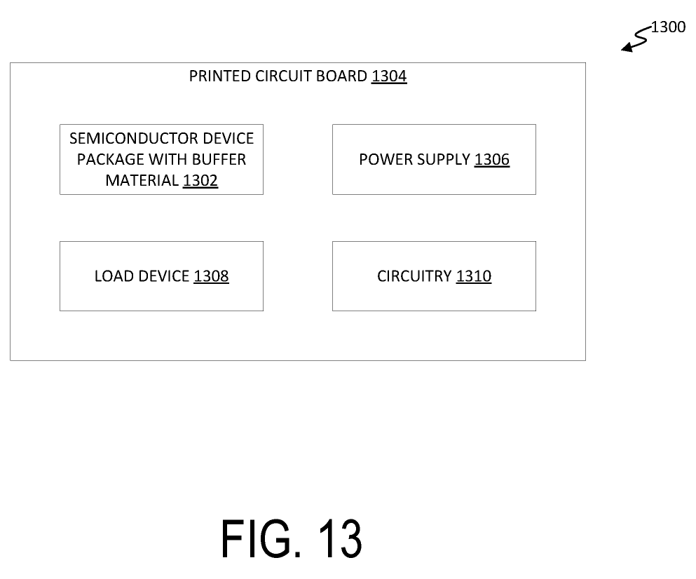

FIG. 13 illustrates a system 1300 comprising a semiconductor device package 1302 comprising a buffer material, in accordance with any of the examples disclosed herein. The system 1300 includes a printed circuit board 1304 and various components connected to the printed circuit board. In the example depicted, these components include semiconductor device package 1302, power supply 1306, load device 1308, and circuitry 1310. The components may be coupled together in any suitable manner, such as through conductive traces on the semiconductor device package 1302.

The semiconductor device package 1302 may include any suitable semiconductor device package with a buffer material, such as those described herein (e.g., plug-in semiconductor device package 500, surface mount semiconductor device package 1100) or variations thereof.

One or more power supplies 1306 may provide electrical power to the components attached to the printed circuit board 1304. A power supply 1306 may include any suitable source of electrical power, such as, for example, a direct current power supply, an alternating current power supply, or a battery.

Load device 1308 may comprise any suitable device connected to, powered by, or controlled by the semiconductor device package 1302. For example, the load device 1308 may include an electrical or mechanical device, such as a motor, solenoid, actuator, lighting device, battery pack, capacitor bank, power supply, inverter, heater, amplifier, or other suitable device.

Circuitry 1310 may include any other suitable circuitry of the system 1300, such as one or more integrated circuits, microcontrollers, processors, resistors, capacitors, diodes, transistors, inductors, transformers, switches, or other suitable circuitry.

In various embodiments, one or more of the illustrated components (or additional components) may be located off of the printed circuit board 1304 and coupled to printed circuit board 1304 via any suitable connectors.

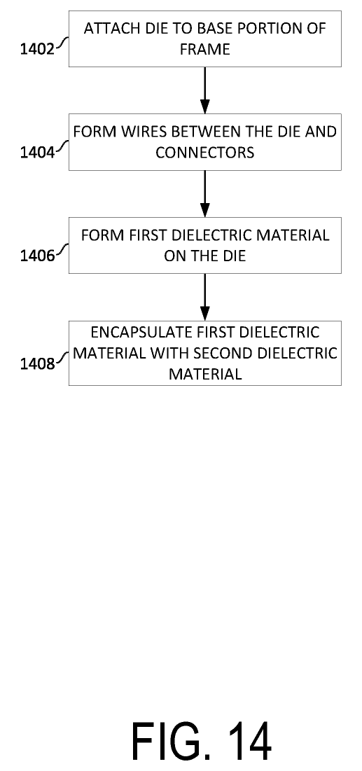

FIG. 14 illustrates a flow for forming a semiconductor device package comprising a buffer material. At 1402, a die is attached to a base portion of a frame. At 1404, wires are formed between the die and connectors of the frame. At 1406, a first dielectric material (e.g., a buffer material) is formed on the die. In some instances, the first dielectric material may also be formed on a portion of the base portion of the frame. At 1408, the first dielectric material is encapsulated with a second dielectric material (e.g., an encapsulating material).

As used herein, the term “or” is intended to be inclusive rather than exclusive. That is, unless otherwise indicated or as would be apparent to one of skill in the art, the use of “or” should be interpreted to mean “and/or.” For example, the phrase “A or B” should be understood to mean “A, B, or both A and B.” The singular terms "a," "an," and "the" are intended to encompass their plural counterparts as well, unless it is clear from the context that a different interpretation is intended. Herein, when a list of items is preceded by phrases such as “at least one of” or “one or more of,” it is intended to allow for any combination of the listed elements.

The terms “above”, “over,” “under,” “between,” and “on,” as used herein, describe the relative positioning of components or materials. For instance, one layer being over or under another layer may encompass direct contact of the layers or the presence of one or more intermediate layers. Similarly, a layer described as being between two others may be in contact with both other layers or separated by one or more additional layers. Conversely, when a layer is “on” another layer, at least a portion of the layer is in direct physical contact with the underlying layer.

In the drawings, while some structural or method features may be shown in specific arrangements or orderings, such specific arrangements or orderings may be optional. In some examples, such features may be arranged in a different manner or order than shown in the drawings. Additionally, the inclusion of a structural or method feature in a particular drawing is not meant to imply that such feature is present in all examples, and, in some examples, such feature may not be included or may be combined with other features. Further, the various examples shown in the drawings are illustrative representations and may not be drawn to scale. In some instances, the same or similar reference numerals may be used to designate the same or similar features in different drawings.

Example 1 includes a semiconductor device package comprising a frame comprising a base portion and a plurality of connectors extending outwardly from the base portion; a die attached to the base portion of the frame, the die comprising a semiconductor device comprising at least one terminal coupled to at least one of the plurality of connectors of the frame; a first dielectric material in contact with at least a portion of a top surface of the die and a portion of the base portion of the frame; and a second dielectric material encapsulating the first dielectric material.

Example 2 includes the subject matter of Example 1, and wherein the first dielectric material comprises an underfill material.

Example 3 includes the subject matter of any of Examples 1 and 2, and further including a cavity formed within the base portion of the frame, wherein the die is attached to the frame within the cavity of the base portion of the frame.

Example 4 includes the subject matter of any of Examples 1-3, and wherein the first dielectric material is at least partially within the cavity of the frame.

Example 5 includes the subject matter of any of Examples 1-4, and wherein a height of the first dielectric material is equal to or less than a depth of the cavity of the frame.

Example 6 includes the subject matter of any of Examples 1-5, and wherein the first dielectric material is entirely within the cavity of the frame.

Example 7 includes the subject matter of any of Examples 1-6, and wherein the first dielectric material is in contact with a majority of a top surface of the die.

Example 8 includes the subject matter of any of Examples 1-7, and wherein the first dielectric material is in contact with a plurality of wires that couple the at least one terminal of the semiconductor device to the at least one of the plurality of connectors of the frame.

Example 9 includes the subject matter of any of Examples 1-8, and wherein the first dielectric material is in contact with a polyimide layer of the die.

Example 10 includes the subject matter of any of Examples 1-9, and wherein the second dielectric material comprises an epoxy molding compound.

Example 11 includes the subject matter of any of Examples 1-10, and wherein the second dielectric material has a through-hole formed therein.

Example 12 includes the subject matter of any of Examples 1-11, and wherein the semiconductor device package comprises a plug-in package.

Example 13 includes the subject matter of any of Examples 1-11, and wherein the semiconductor device package comprises a surface mount package.

Example 14 includes a method for forming a semiconductor device package, the method comprising attaching a die comprising a semiconductor device to a base portion of a frame, the frame comprising the base portion and a plurality of connectors extending outwardly from the base portion; forming a first dielectric material on the die and on a portion of the frame; and encapsulating the first dielectric material with a second dielectric material.

Example 15 includes the subject matter of Example 14, and further including forming a plurality of wires between the die and the plurality of connectors.

Example 16 includes the subject matter of any of Examples 14-15, and wherein the first dielectric material comprises an underfill material and the second dielectric material comprises an epoxy molding compound.

Example 17 includes an apparatus comprising a semiconductor device package comprising a frame comprising a surface and a plurality of connectors; a die attached to the surface, the die comprising a semiconductor device comprising at least one terminal coupled to at least one of the plurality of connectors of the frame; a first dielectric material in contact with at least a portion of a top surface of the die; and a second dielectric material on the first dielectric material.

Example 18 includes the subject matter of Example 17, and wherein the surface of the frame is recessed from a second surface of the frame.

Example 19 includes the subject matter of any of Examples 17 and 18, and further including a printed circuit board, wherein the plurality of connectors of the frame are connected to the printed circuit board.

Example 20 includes the subject matter of any of Examples 17-19, and further including an electrical or mechanical device coupled to the semiconductor device package through the printed circuit board.

While the concepts of the present disclosure are susceptible to various modifications and alternative forms, specific examples thereof have been shown in the drawings and described herein in detail. However, the concepts of the present disclosure are not limited to the particular forms disclosed, but on the contrary, all modifications, equivalents, and alternatives consistent with the present disclosure and the appended claims are also covered. Moreover, all examples described herein may be combined in any manner.

1. A semiconductor device package comprising:
a frame comprising a base portion and a plurality of connectors extending outwardly from the base portion;
a die attached to the base portion of the frame, the die comprising a semiconductor device comprising at least one terminal coupled to at least one of the plurality of connectors of the frame;
a first dielectric material in contact with at least a portion of a top surface of the die and a portion of the base portion of the frame; and
a second dielectric material encapsulating the first dielectric material.

2. The semiconductor device package of claim 1, wherein the first dielectric material comprises an underfill material.

3. The semiconductor device package of claim 1, further comprising a cavity formed within the base portion of the frame, wherein the die is attached to the frame within the cavity of the base portion of the frame.

4. The semiconductor device package of claim 3, wherein the first dielectric material is at least partially within the cavity of the frame.

5. The semiconductor device package of claim 4, wherein a height of the first dielectric material is equal to or less than a depth of the cavity of the frame.

6. The semiconductor device package of claim 3, wherein the first dielectric material is entirely within the cavity of the frame.

7. The semiconductor device package of claim 1, wherein the first dielectric material is in contact with a majority of a top surface of the die.

8. The semiconductor device package of claim 1, wherein the first dielectric material is in contact with a plurality of wires that couple the at least one terminal of the semiconductor device to the at least one of the plurality of connectors of the frame.

9. The semiconductor device package of claim 1, wherein the first dielectric material is in contact with a polyimide layer of the die.

10. The semiconductor device package of claim 1, wherein the second dielectric material comprises an epoxy molding compound.

11. The semiconductor device package of claim 1, wherein the second dielectric material has a through-hole formed therein.

12. The semiconductor device package of claim 1, wherein the semiconductor device package comprises a plug-in package.

13. The semiconductor device package of claim 1, wherein the semiconductor device package comprises a surface mount package.

14. A method for forming a semiconductor device package, the method comprising:
attaching a die comprising a semiconductor device to a base portion of a frame, the frame comprising the base portion and a plurality of connectors extending outwardly from the base portion;
forming a first dielectric material on the die and on a portion of the frame; and
encapsulating the first dielectric material with a second dielectric material.

15. The method of claim 14, further comprising forming a plurality of wires between the die and the plurality of connectors.

16. The method of claim 14, wherein the first dielectric material comprises an underfill material and the second dielectric material comprises an epoxy molding compound.

17. An apparatus comprising:
a semiconductor device package comprising:
a frame comprising a surface and a plurality of connectors;
a die attached to the surface, the die comprising a semiconductor device comprising at least one terminal coupled to at least one of the plurality of connectors of the frame;
a first dielectric material in contact with at least a portion of a top surface of the die; and
a second dielectric material on the first dielectric material.

18. The apparatus of claim 17, wherein the surface of the frame is recessed from a second surface of the frame.

19. The apparatus of claim 17, further comprising a printed circuit board, wherein the plurality of connectors of the frame are connected to the printed circuit board.

20. The apparatus of claim 19, further comprising an electrical or mechanical device coupled to the semiconductor device package through the printed circuit board.
